(19) United States
(12) Patent Application Publication
(10) Pub. No.: US 2007/0296023 A1
(43) Pub. Date: Dec. 27, 2007

(54) Charge Monitoring Devices and Methods for Semiconductor Manufacturing

(75) Inventors: Chao-I Wu, Zhubei City (TW); Ming Hsiu Lee, Ju-Bei City (TW)

Correspondence Address: MACRONIX;C/O HAYNES BEFFEL & WOLFELD LLP, P. O. BOX 366, HALF MOON BAY, CA, 94019, US

(73) Assignee: Macronix International Co., Ltd., Hsinchu (TW)

(21) Appl. No.: 11/425,469

(22) Filed: Jun. 21, 2006

(51) Int. Cl. H01L 29/792

(52) U.S. Cl. 257/324

(57) ABSTRACT

A charge monitoring device is described for monitoring charging effect during semiconductor manufacturing. In a first aspect of the invention, a charge storage MOS memory structure comprises a substrate body, an oxide-nitride-oxide structure that overlays a top surface of the substrate and extends above the edges between a source region and a drain region, and a polygate formed over the oxide-nitride-oxide structure. When a charging source, such as UV light or plasma, is projected onto the charge storage device, the polygate of the charge storage device protects the nitride layer from charging effect The light source charges side walls of the oxide-nitride-oxide structure.

### BACKGROUND OF THE INVENTION

1. Field of the Invention

The present invention relates generally to electrically programmable and erasable memory and more particularly to charge storage devices for monitoring charging effect.

2. Description of Related Art

Electrically programmable and erasable nonvolatile memory technologies based on charge storage structures known as Electrically Erasable Programmable Read-Only Memory (EEPROM) and flash memory are used in a variety of modem applications. A flash memory is designed with an array of memory cells that can be independently programmed and read. Sense amplifiers in a flash memory are used to determine the data value or values stored in a nonvolatile memory. In a typical sensing scheme, an electrical current through the memory cell being sensed is compared to a reference current by a current sense amplifier.

A number of memory cell structures are used for EEPROM and flash memory. As the dimensions of integrated circuits shrink, greater interest is arising for memory cell structures based on charge trapping dielectric layers, because of the scalability and simplicity of the manufacturing processes. Memory cell structures based on charge trapping dielectric layers include structures known by N-bit memory. These memory cell structures store data by trapping charge in a charge trapping dielectric layer, such as silicon nitride. As negative charge is trapped, the threshold voltage of the memory cell increases. The threshold voltage of the memory cell is reduced by removing negative charge from the charge trapping layer.

N-bit devices use a relatively thick bottom oxide, e.g. greater than 3 nanometers, and typically about 5 to 9 nanometers, to prevent charge loss. Instead of direct tunneling, band-to-band tunneling induced hot hole injection BTBTHH can be used to erase the cell. However, the hot hole injection causes oxide damage leading to charge loss in the high threshold cell and charge gain in the low threshold cell. Moreover, the erase time must be increased gradually during program and erase cycling due to the hard-to-erase accumulation of charge in the charge trapping structure. This accumulation of charge occurs because the hole injection point and electron injection point do not coincide with each other, and some electrons remain after the erase pulse. In addition, during the sector erase of an N-bit flash memory device, the erase speed for each cell is different because of process variations (such as channel length variation). This difference in erase speed results in a large Vt distribution of the erase state, where some of the cells become hard to erase and some of them are over-erased. Thus the target threshold Vt window is closed after many program and erase cycles and poor endurance is observed. This phenomenon will become more serious as the technology continues scaling down.

A traditional floating gate device stores 1 bit of charge in a conductive floating gate. N-bit devices has a plurality of cells where each N-bit cell provides two bits of flash cells that store charge in an Oxide-Nitride-Oxide (ONO) dielectric. In a typical structure of an N-bit memory cell, a nitride layer is used as a trapping material positioned between a top oxide layer and a bottom oxide layer. The ONO layer structure effectively replaces the gate dielectric in floating gate devices. The charge in the ONO dielectric with a nitrite layer may be either trapped on the left side or the right side of an N-bit cell.

It is desirable to design simpler charge storage structures for monitoring charging effect in charge trapping memories as well as providing direction effect for the charge storage structures.

### SUMMARY OF THE INVENTION

The present invention describes a charge monitoring device for monitoring charging effect during semiconductor manufacturing. In a first aspect of the invention, a charge storage MOS (CS-MOS) memory structure comprises a substrate body, an oxide-nitride-oxide structure that overlays a top surface of the substrate and extending above the edges between a source region and a drain region, and a polygate formed over the oxide-nitride-oxide structure. When a charging source, such as UV light or plasma, is projected onto the charge storage device, the polygate of the charge storage device protects the nitride layer from charging effect. The light source charges side walls of the oxide-nitride-oxide structure. In a corresponding layout structure, a source/drain strip extends substantially in a first direction, while a polygate strip extends substantially in a second direction that is approximately orthogonal with the source/drain strip in the first direction. The polygate strip having a length Lg measured from the width of the polygate strip, and a width Wg measured from the width of the source/drain strip.

In a second aspect of the invention, a charge storage virtual ground (CS-VG) memory structure comprises a substrate body, an oxide-nitride-oxide structure that overlays a top surface of the substrate body, and a polygate formed over the oxide-nitride-oxide structure. When a light source is projected onto the charge storage device, a top surface of the polygate blocks light from penetrating the polygate. The light source charges side walls of the oxide-nitride-oxide structure. In a corresponding layout structure, a source strip extends substantially in a first direction, a drain strip extends substantially in the first direction, while a polygate strip extends substantially in a second direction that is approximately orthogonal with the source and drain strips in the first direction. The polygate strip has a length Lg measured from a gap between the source strip and the drain strip, and a width Wg measured from the width of the polygate strip.

Broadly stated, a charging monitor device comprises a substrate body having a channel separating a first region and a second region; a charging trapping structure overlying a top surface of the channel in the substrate body, the charging trapping structure having sides; and a polygate overlying a top surface of the charge trapping structure, the polygate having a top surface and sides that align with the sides of the charge trapping structure; wherein a charging source projects charges onto the top surface of the polygate, the sides of the polygate and the sides of the charge trapping structure, the top surface of the polygate substantially blocks the charges from penetrating the top surface of the polygate, and the charging source provides charges to the sides of the charge trapping structure.

Advantageously, the present invention provides simpler charge storage device structures for monitoring charging effect. The present invention also advantageously provides different device structures for controlling the sensibility of the charging effect.

The structures and methods of the present invention are disclosed in the detailed description below. This summary does not purport to define the invention. The invention is defined by the claims. These and other embodiments, features, aspects, and advantages of the invention will become better understood when read in conjunction with the following description, appended claims and accompanying drawings.

### BRIEF DESCRIPTION OF THE DRAWINGS

The invention will be described with respect to specific embodiments thereof, and reference will be made to the drawings, in which:

FIG. 1A is a process diagram illustrating a cross-sectional view of a charge storage MOS memory structure in accordance with the present invention.

FIG. 1B is a layout diagram illustrating a top view of the charge storage MOS memory structure in accordance with the present invention.

FIG. 2A is a process diagram illustrating a cross-sectional view of a charge storage virtual ground memory structure in accordance with the present invention.

FIG. 2B is a layout diagram illustrating a top view of a charge storage virtual ground memory structure in accordance with the present invention.

FIG. 3A is a process diagram illustrating a cross-sectional view of the charge storage MOS memory structure showing charging locations and a device current path in accordance with the present invention.

FIG. 3B is a process diagram illustrating a top view of the charge storage MOS memory structure showing charging locations and a device current path in accordance with the present invention.

FIG. 4 is a graphical diagram illustrating an experimental result of an IV curve of the charge storage MOS memory structure in accordance with the present invention.

FIG. 5A is a process diagram illustrating a cross-sectional view of the charge storage virtual ground memory structure showing charging locations and a device current path in accordance with the present invention.

FIG. 5B is a process diagram illustrating a top view of the charge storage virtual ground memory structure showing charging locations and a device current path in accordance with the present invention.

FIG. 6 is a graphical diagram illustrating an experimental result of the charge storage virtual ground memory structure in accordance with the present invention.

FIGS. 7A-7D are layout diagrams illustrating various directions for monitoring charging effect in the charge storage MOS memory structure in accordance with the present invention.

FIGS. 8A-8D are layout diagrams illustrating various directions for monitoring charging effect in the charge storage virtual ground memory structure in accordance with the present invention.

FIG. 9 is a block diagram illustrating a silicon wafer with placement of various charge monitor structures in accordance with the present invention.

### DETAILED DESCRIPTION

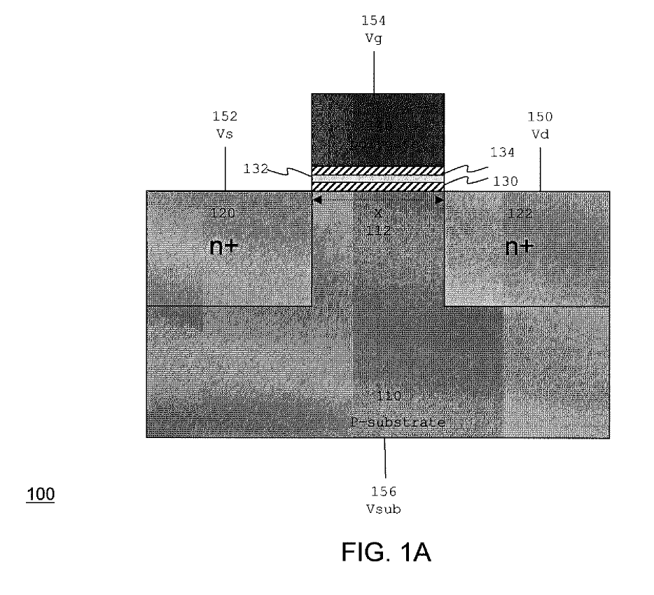

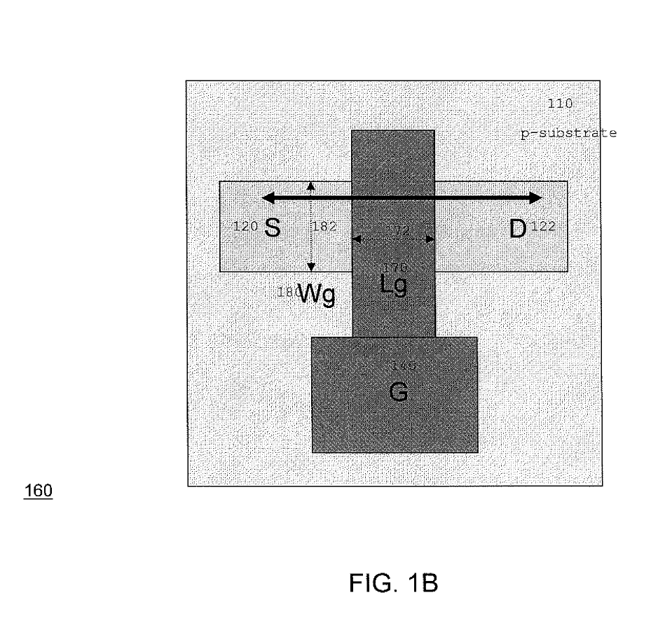

A description of structural embodiments and methods of the present invention is provided with reference to FIGS. 1-9. It is to be understood that there is no intention to limit the invention to the specifically disclosed embodiments, but that the invention may be practiced using other features, elements, methods and embodiments. Like elements in various embodiments are commonly referred to with like reference numerals.

FIG. 1A is a process diagram illustrating a cross-sectional view of a CS-MOS memory structure 100. The CS-MOS memory structure 100 comprises a p-substrate 110 with n+ doped regions 120 and 122, and a p-doped region between the n+ doped regions 120 and 122. A channel width X 112 of the p-substrate 1 10 is positioned between the n+ doped region 120 on the left end and the n+ doped region 122 on the right end. A bottom dielectric structure 130 (bottom oxide) overlays a top surface of the channel width X 112 of the substrate 110; a charge trapping structure 132 (e.g. silicon nitride layer) overlays the bottom dielectric structure 130; a top dielectric structure (top oxide) 134 overlays the charge trapping structure 132; and an n+ polygate 140 overlays the top dielectric structure 134. The combination of the bottom dielectric structure 130, the charge trapping structure 132, and the top dielectric structure 134 is commonly referred as an ONO (oxide-nitride-oxide) structure. The width of the ONO structure aligns with the channel width X 112 of the p-substrate 110. Representative top dielectrics include silicon dioxide and silicon oxynitride having a thickness of about 5 to 10 nanometers, or other similar high dielectric constant materials including for example Al₂O₃. Representative bottom dielectrics include silicon dioxide and silicon oxynitride having a thickness of about 3 to 10 nanometers, or other similar high dielectric constant materials. Representative charge trapping structures include silicon nitride having a thickness of about 3 to 9 nanometers, or other similar high dielectric constant materials, including metal oxides such as Al₂O₃, HfO₂, CeO₂, and others. The charge trapping structure may be a discontinuous set of pockets or particles of charge trapping material, or a continuous layer as shown in the drawing.

Bias voltages can be applied to the CS-MOS memory structure 100 to measure electrical characteristics. A collection of different measured data, including I-V curve, Vt shift, and Gm variation, can be used to check the charging effect. For example, a drain voltage 150 VD is applied with 1.6V to the n+ doped region 122 and a source voltage VS 152 is applied with 0 volts to the n+ doped region 120, and the sweeping of a gate voltage Vg 154 from 0 volts to 6 volts for checking the flow of an electrical current. Alternatively, the gate voltage Vg 154 remains at a constant value at 6 volts. A substrate voltage Vsub 156 is connected to the p-substrate 10. A higher charged MOS memory structure 100 causes smaller current as well as high Vt level.

The memory cell for N-bit -like cells has, for example, a bottom oxide with a thickness ranging from 3 nanometers to 10 nanometers, a charge trapping layer with a thickness ranging from 3 nanometers to 9 nanometers, and a top oxide with a thickness ranging from 5 nanometers to 10 nanometers. The memory cell for SONOS-like cells has, for example, a bottom oxide with a thickness ranging from 1 nanometer to 3 nanometers, a charge trapping layer with a thickness ranging from 3 nanometers to 9 nanometers, and a top oxide with a thickness ranging from 3 nanometers to 10 nanometers.

As generally used herein, programming refers to raising the threshold voltage of a memory cell and erasing refers to lowering the threshold voltage of a memory cell. However, the invention encompasses both products and methods where programming refers to raising the threshold voltage of a memory cell and erasing refers to lowering the threshold voltage of a memory cell, and products and methods where programming refers to lowering the threshold voltage of a memory cell and erase refers to raising the threshold voltage of a memory cell.

FIG. 1B is a layout diagram 160 illustrating a top view of the CS-MOS memory structure 100 with layers of a p-substrate 110, the n+ doped region 120 operating as a source, the n+ doped region 122 operating as a drain and the polygate 140. The memory structure has a channel length denoted by the symbol Lg 170 and a channel width denoted by the symbol Wg 180. The channel length Lg 170 is defined by the length in the horizontal direction of the polygate 140, as indicated by the double-ended arrow 172. The channel width Wg 180 is defined by the length in the horizontal direction of the source 120 and the drain 122, as indicated by the double-ended arrow 182.

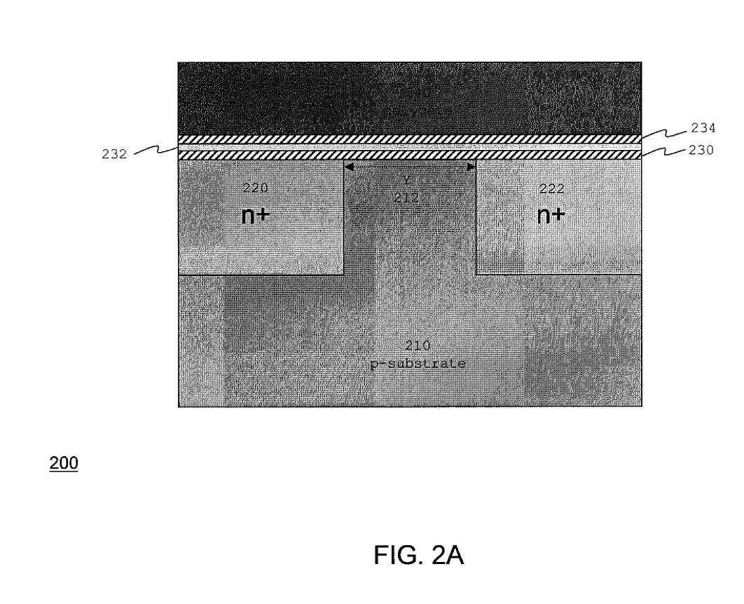

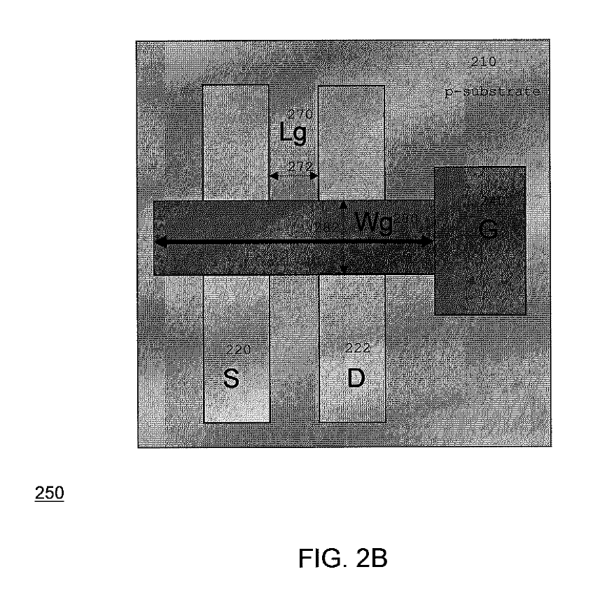

FIG. 2A is a process diagram illustrating a cross-sectional view of a CS-VG memory structure 200. The charge storage virtual ground memory structure 200 comprises a p-substrate 210 with n+ doped regions 220 and 222, and a p-doped region between the n+ doped regions 220 and 222. A channel width Y 212 of the p-substrate 210 is positioned between the n+ doped region 220 on the left end and the n+ doped region 222 on the right end. A bottom dielectric structure 230 overlays across top surfaces of the n+ doped region 220, the channel width Y 212, and the n+ doped region 220. A charge trapping structure 232 overlays the bottom dielectric structure 230, and a top dielectric structure 234 overlays the charge trapping structure 232, and a polygate 240 overlays the top dielectric structure 234. The combination of the bottom dielectric structure 230, the charge trapping structure 232, and the top dielectric structure 234 is commonly referred as an ONO structure. The width of the ONO structure aligns with the entire width measured by the n+ doped region 220, the channel width Y 212, and the n+ doped region 220.

FIG. 2B is a layout diagram 250 illustrating a top view of CS-VG memory structure 200 with layers of the p-substrate 210, the source strip 220, the drain strip 222 and the polygate 240. The memory structure has a channel length denoted by the symbol Lg 270 and a channel width denoted by the symbol Wg 280. The channel length Lg 270 is defined by a gap between the source strip 220 and the drain strip 222, as indicated by the double-ended arrow 272. The channel width Wg 280 is defined by the length in the vertical direction of the polygate 240, as indicated by the double-ended arrow 282.

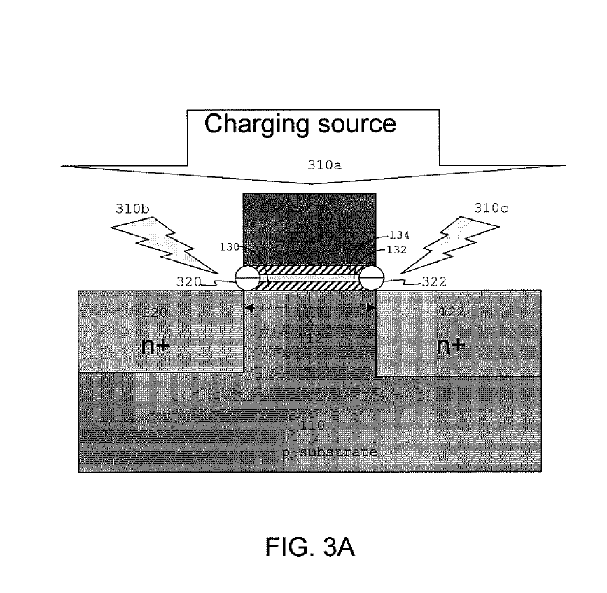

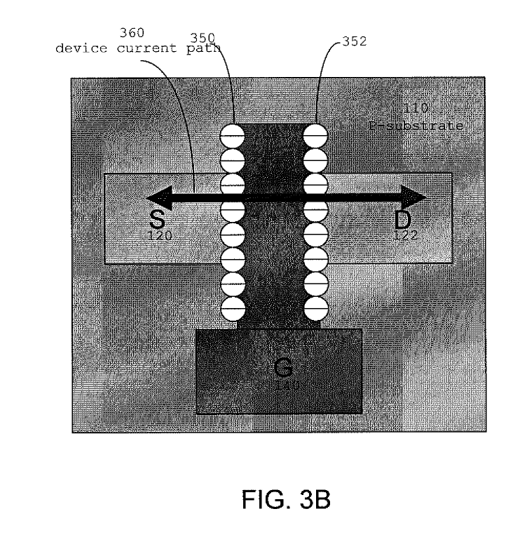

FIG. 3A is a process diagram illustrating a cross-sectional view of the CS-MOS memory structure 100 showing charging locations and a device current path. A charging source such as a UV light emits lights in different directions including projecting light 310a from the top, projecting light 310b from the left side, and projecting light 310c from the right side. The polygate 140 blocks entirely or substantially the projected light 310a from entering the polygate 140 and the charge trapping structure 132. The light 310b from the left side charges a left sidewall 320 of the charge trapping structure 132. The light 310c from the right side charges a right sidewall 322 of the charge trapping structure 132.

FIG. 3B is a process diagram illustrating a top view of the CS-MOS memory structure 100 showing charging locations and a device current path. Because the polygate 140 blocks charges from the projected light 310a from entering the polygate 140, a plurality of charges 350 gather along the left sidewall 320 and a plurality of charges 352 gather along the right sidewall 322 of the charge trapping structure 132. A device current path 360 flows bidirectionally between the source 120 and the drain 122.

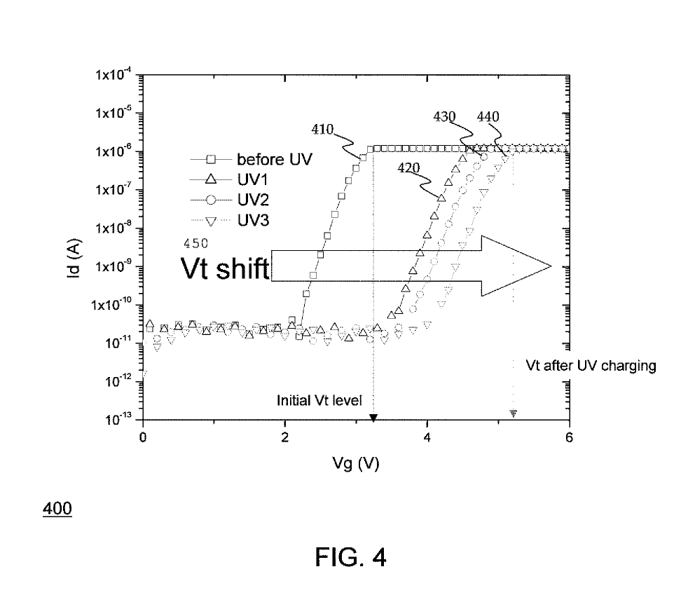

FIG. 4 is a graphical diagram 400 illustrating an experimental result of an IV (Id-Vg) curve of the CS-MOS memory structure 100. The graphical diagram 400 shows a first curve 410 before the application of UV light, a second curve 420 with the application of UV1 light, a third curve 430 with the application of UV2 light, and a fourth curve 440 with the application of UV3 light. A threshold voltage Vt 450 is used to monitor the charge behavior of the CS-MOS memory structure 100. The voltage level of the Vt shift 450 increases with the increase in the amount of charge time of UV light so that the effect of UV charging effect can be monitored.

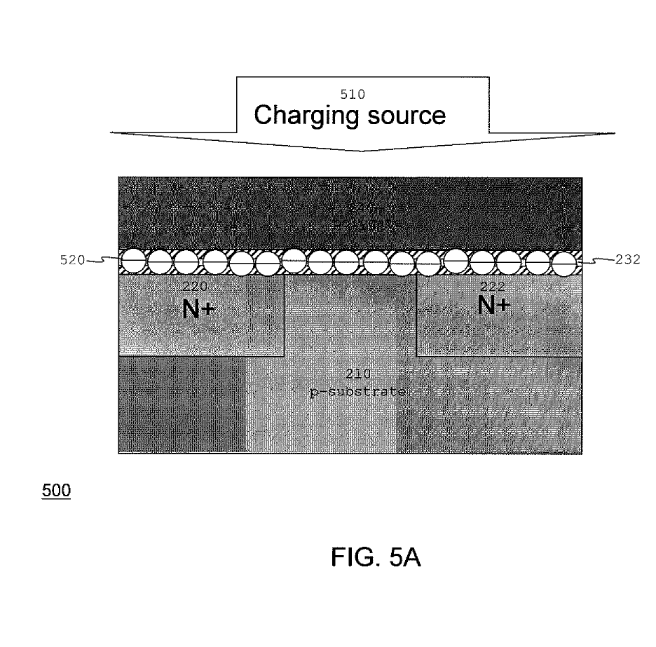

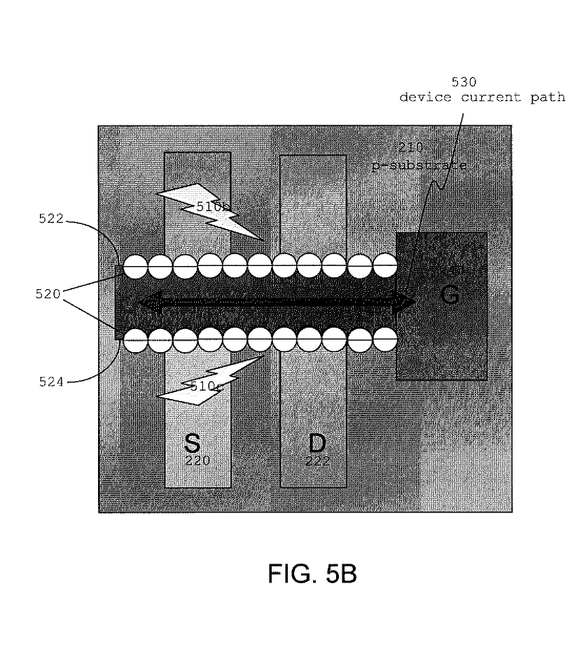

FIG. 5A is a process diagram illustrating a cross-sectional view of the CS-VG memory structure 200 showing charging locations and a device current path. A charging source 510 such as a UV light emits light in the direction of a polygate 240. The polygate 240 blocks entirely or substantially the projected light 510 from entering the polygate 240 and the charge trapping structure 232. However, the light projected by the charging source 510 charges side walls of a gate region of the polygate 240, as indicated by charges 520 in the charge trapping structure 232.

FIG. 5B is a layout diagram illustrating a top view of the CS-VG memory structure showing charging locations and a device current path. Although the polygate 240 blocks charges from the projected light 510 from entering the polygate 240, the charging source 510 also projects light near the side walls 522 and 524 of the gate region as to inject a plurality of charges 520 into the charge trapping structure 232. A device current path 530 flows bidirectionally along the length of the polygate 240. While the charges gather vertically along sides of the polygate 140 in the layout diagram of FIG. 3B, the charges gather horizontally along sides of the polygate 240 in the layout diagram of FIG. 5B.

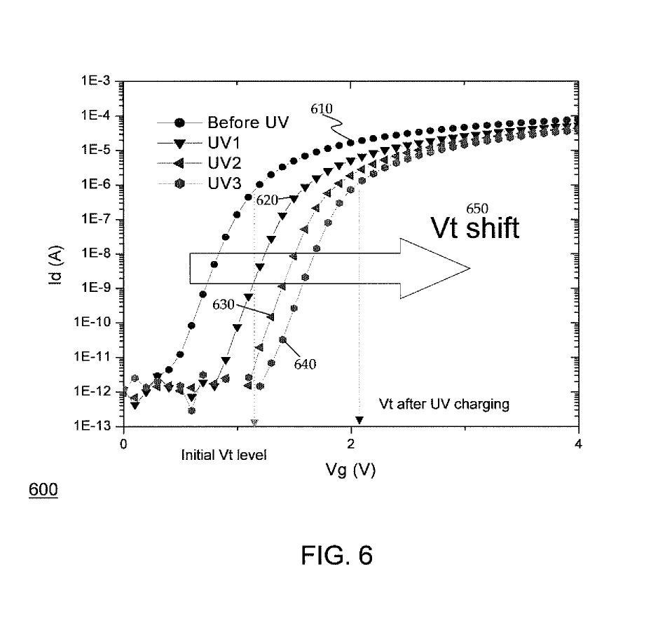

FIG. 6 is a graphical diagram 600 illustrating an experimental result of an IV (Id-Vg) curve of the CS-VG memory structure 200. The graphical diagram 600 shows a first curve 610 before the application of UV light, a second curve 620 with the application of UV1 light, a third curve 630 with the application of UV2 light, and a fourth curve 640 with the application of UV3 light. A threshold voltage Vt 650 is used to monitor the charge behavior of a memory cell. The voltage shift level of the Vt 650 increases with the increase in the amount of charge time of UV light so that the effect of UV charging effect can be monitored.

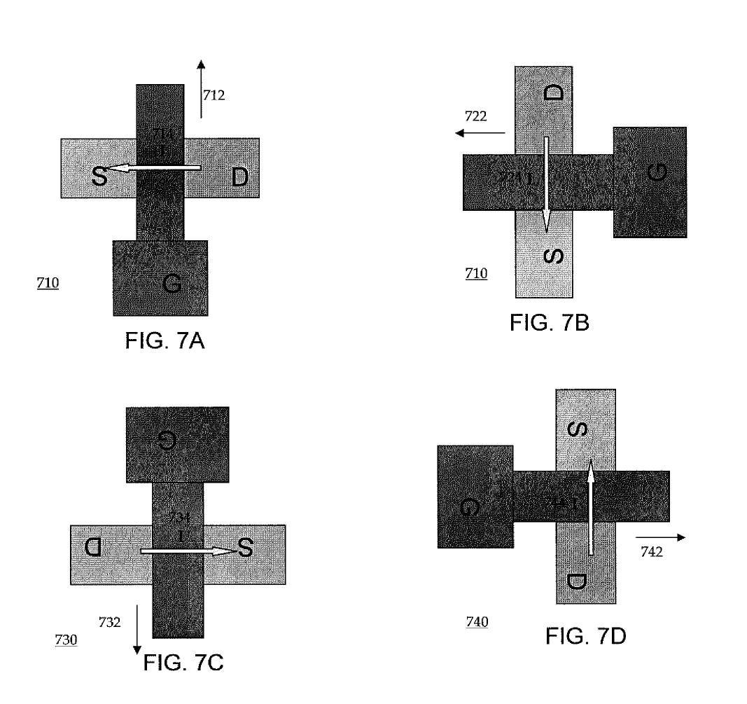

FIGS. 7A-7D are layout diagrams 710, 720, 730, 740, illustrating various directions for monitoring charging effect in a CS-MOS memory structure. Each layout in the layout diagrams 710, 720, 730, 740 shows a different direction flow of the CS-MOS memory structure 100 for use with monitoring a different charging behavior. In the layout diagram 710, the polygate 140 is placed in the north direction 712 with a direction effect in a north direction and an electrical current flow toward the west direction 714. In the layout diagram 720, the polygate 140 is placed in the west direction 722 with a direction effect in a west direction and an electrical current flow toward the south direction 724. In the layout diagram 730, the polygate 140 is placed in the south direction 732 with a direction effect in a south direction and an electrical current flow toward the east direction 734. In the layout diagram 740, the polygate 140 is placed in the north direction 742 with a direction effect in an east direction and an electrical current flow toward the west direction 744.

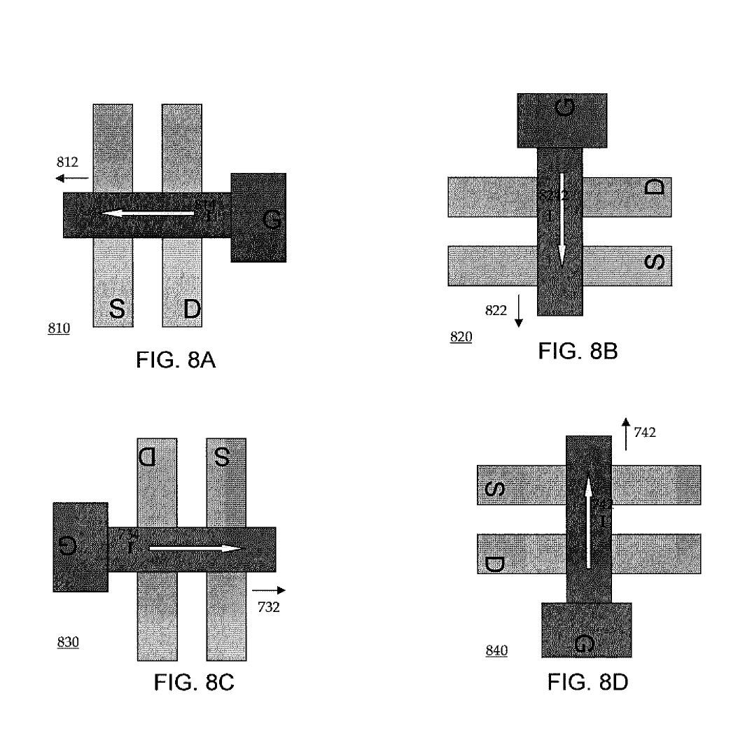

FIGS. 8A-8D are layout diagrams illustrating various directions for monitoring charging effect in the CS-VG memory structure 200. Each layout in the layout diagrams 810, 820, 830, 840 shows a different direction flow of a CS-MOS memory structure for use with monitoring a different charging behavior. In the layout diagram 810, the polygate 240 is placed in the west direction 812 with a direction effect in an cast direction and an electrical current flow toward the west direction 814. In the layout diagram 820, the polygate 240 is placed in the south direction 822 with a direction effect in a south direction and an electrical current flow toward the south direction 824. In the layout diagram 830, the polygate 240 is placed in the east direction 832 with a direction effect on an east direction and an electrical current flow toward the east direction 834. In the layout diagram 840, the polygate 840 is placed in the north direction 842 with a direction effect on a north direction and an electrical current flow toward the north direction 844.

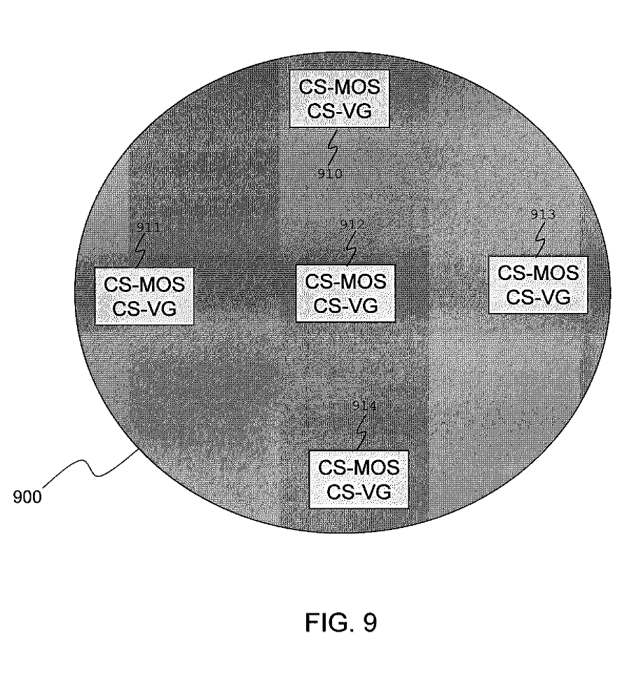

FIG. 9 is a block diagram illustrating a silicon wafer 900 with placement of various charge monitor structures 910, 911, 912, 913 and 914 to sense charging effect on a single wafer. Each of the charge monitor structures 910-914 includes a CS-MOS memory structure and a CS-VG memory structure. The various charge monitor structures 910-914 can be placed at any position on the silicon wafer 900 to monitor the charging behavior in a particular area of the silicon wafer 900.

The invention has been described with reference to specific exemplary embodiments. For example, the charge storage structures in the present invention are applicable to any type or variations of a charge trapping memory including both n-channel and p-channel SONOS type of devices and floating gate memory. Accordingly, the specification and drawings are to be regarded as illustrative of the principles of this invention rather than restrictive, the invention is defined by the following appended claims.

We claim:

1. A charging monitor device, comprising:
a substrate body having a channel separating a first region and a second region;
a charging trapping structure overlying a top surface of the channel in the substrate body, the charging trapping structure having sides; and
a polygate overlying a top surface of the charge trapping structure, the polygate having a top surface and sides that align with the sides of the charge trapping structure;
wherein a charging source projects charges onto the top surface of the polygate, the sides of the polygate and the sides of the charge trapping structure, the top surface of the polygate substantially blocking the charges from penetrating the top surface of the polygate, the charging source providing charges to the sides of the charge trapping structure.

2. The charging monitor device of claim 1, wherein the charge trapping structure comprises an oxide-nitride-oxide stack.

3. The charging monitor device of claim 1, wherein the charge trapping structure comprises a nitride-oxide stack.

4. The charging monitor device of claim 1, wherein the charge trapping structure comprises an oxide-nitride-oxide-nitride-oxide stack.

5. The charge monitor device of claim 1, wherein the first region comprises an n+ doped source region and the second region comprises an n+ doped drain region.

6. The charge monitor device of claim 1, further comprising a source terminal connected to the first region; a drain terminal connected to the second region; and a gate terminal connected to the polygate, wherein the source terminal is supplied with zero volts, the drain terminal is supplied with 1.6 volts, and the gate terminal is supplied with a variable voltage between about zero volts to about 6 volts to measure an electrical current flowing from the second region to the first region.

7. The charge monitor device of claim 1, wherein the charging source comprises a UV light source.

8. A charging monitor device, comprising:
a substrate body having a top surface;
a charge trapping structure overlying the substrate body and having sides; and
a polygate overlying the nitride trapping structure, the polygate having a top surface and sides that align with the sides of the charge trapping structure;
wherein a light source projects charges onto the polygate, the sides of the polygate and the side of the charge trapping structure, the top surface of the polygate substantially blocks the charges from penetrating the top surface of the polygate, and the light source provides the charges to the sides of the charge trapping structure.

9. The charging monitor device of claim 8, wherein the nitride trapping structure comprises an oxide-nitride-oxide stack.

10. The charging monitor device of claim 8, wherein the nitride trapping structure comprises a nitride-oxide stack.

11. The charging monitor device of claim 8, wherein the charge trapping structure comprises an oxide-nitride-oxide-nitride-oxide stack.

12. The charge monitor device of claim 8, wherein the first region comprises an n+ doped source region and the second region comprises an n+ doped drain region.

13. The charge monitor device of claim 1, wherein the charging source comprises a UV light source.

14. A layout structure of a charge storage MOS memory device, comprising:
a source/drain strip extending substantially in a first direction; and
a polygate strip overlaying the source/drain strip and extending substantially in a second direction that is approximately orthogonal to the source/drain strip in the first direction, the charge section of the polygate having sides in the second direction for storing charges along the sides of the charge section of the polygate, wherein the device has a channel length defined by a width of the charge section of the polygate strip and a channel width defined by a width of the source/drain strip.

15. The layout structure of claim 14, wherein the first direction of the source/drain strip comprises a horizontal east-west direction, and an electrical current flowing from an east to a west direction, wherein the device monitors charging effect in a north direction.

16. The structure of claim 14, wherein the first direction of the source/drain strip comprises a vertical north-south direction, and an electrical current flowing from a north to a south direction, wherein the device monitors charging effect in a west direction.

17. The structure of claim 14, wherein the first direction of the source/drain strip comprises a horizontal west-east direction, and an electrical current flowing from a west to an east direction, wherein the device monitors charging effect in a south direction.

18. The structure of claim 14, wherein the first direction of the source/drain strip comprises a south-north direction, and an electrical current flowing from a south to a north direction, wherein the device monitors charging effect in an east direction.

19. A layout structure of a charge storage virtual ground memory device, comprising:
a source strip extending substantially in a first direction;
a drain strip extending substantially in the first direction and in parallel to the source strip; and
a polygate strip overlaying the source and drain strips and extending substantially in a second direction that is approximately orthogonal to the source and drain strips in the first direction, the charge section of the polygate having sides in the second direction for storing charges along the sides of the charge section, wherein the device has a channel length defined by a gap between the source strip and the drain strip and a channel width defined by a length of the charge section of the polygate strip.

20. The structure of claim 19, wherein the first direction of the source and drain strips comprises a vertical direction, and an electrical current flows from an east to a west direction, and wherein the device monitors charging effect in an east direction.

21. The layout structure of claim 19, wherein the first direction of the source and drain strips comprises a horizontal direction, an electrical current flows from a north to a south direction, and wherein the device monitors charging effect in a south direction.

22. The structure of claim 19, wherein the first direction of the source and drain strips comprises a vertical direction, and an electrical current flows from a west to an east direction, and wherein the device monitors charging effect in an east direction.

23. The structure of claim 19, wherein the first direction of the source and drain strips comprises a horizontal direction, an electrical current flows from a north to a south direction, and wherein the device monitors charging effect in a north direction.
